(19) United States
(12) Patent Application Publication
(10) Pub. No.: US 2025/0323028 A1
(43) Pub. Date: Oct. 16, 2025

(54) METHODS FOR EXTENDING MWBC IN SEMICONDUCTOR PROCESSING CHAMBERS

(71) Applicant: Applied Materials, Inc., Santa Clara, CA (US)

(72) Inventors: Tsung-Han Yang, San Jose, CA (US); Zhen Liu, Santa Clara, CA (US); Yixiong Yang, Fremont, CA (US); Xingyao Gao, Santa Clara, CA (US); Yu-Heng Deng, Santa Clara, CA (US); Ya-Hsi Hwang, Sunnyvale, CA (US); Chi H. Ching, Mountain View, CA (US); Gaurav Thareja, Santa Clara, CA (US); Rongjun Wang, Dublin, CA (US)

(73) Assignee: Applied Materials, Inc., Santa Clara, CA (US)

(21) Appl. No.: 18/634,504

(22) Filed: Apr. 12, 2024

(51) Int. Cl. H01J 37/32; C23C 16/06; C23C 16/44; C23C 16/455; C23C 16/50; H01L 21/285

(52) U.S. Cl. CPC H01J 37/32862; C23C 16/06; C23C 16/4405; C23C 16/45536; C23C 16/50; H01J 2237/332; H01L 21/28568

(57) ABSTRACT

Molybdenum deposition methods including depositing molybdenum on one or more wafers in a dry cleaned and conditioned processing chamber to a predetermined total deposition thickness, an amount of particle adders on the one or more wafers increasing with deposition thickness from a first amount to a second amount; and exposing the processing chamber to a plasma treatment to reduce an amount of particle adders formed on subsequent wafers to a third amount below the second amount, the plasma treatment extending a time period between a dry cleaning and re-conditioning of the processing chamber.

### TECHNICAL FIELD

Embodiments of the present disclosure generally relate to methods for treating processing chamber components to increase the mean-wafer-before-clean (MWBC) or the time between preventative maintenance cycles. Embodiments of the present disclosure also relate to methods for molybdenum deposition with improved productivity and MWBC.

### BACKGROUND

Plasma-enhanced Atomic Layer Deposition (PE-ALD) processing chambers used for depositing some types of molybdenum films need frequent cleanings and maintenance. There is a low mean wafers between cleaning (MWBC) due to the properties of the deposition material on the process kit (e.g., consumable parts used in a deposition chamber). The process kit includes, but is not limited to, elements of the deposition chamber that are removable parts that touch reactive chemicals during processing. For example, chamber showerheads, pumping liners, pump shields, etc.

During preconditioning of the processing chamber prior to PE-ALD, molybdenum (Mo) is precoated on the process kit. During PE-ALD, Mo accumulation occurs onto the process kit as well as the wafer, due to, for example, gas-phase Mo precursors introduced into the processing chamber that can land on the process kit. The Mo accumulation on the process kit may cause the adhesion of the precoated Mo layer to the process kit to deteriorate. As a result, particulates from the process kit may dislodge from the process kit and land on the wafer. These particulates are known as “particle adders.” If a dislodged particle adder falls onto the wafer, defects may be created that will reduce the device yield.

In modern semiconductor processing methods that make highly complex integrated circuits, particle adders on the surface can reduce device yield to an unacceptably low level. Moreover, more frequent and time-consuming cleaning operations (i.e., a combination of dry cleaning and preconditioning) increase fabrication times and reduces wafer throughput. For example, dry cleaning and burn-in (preconditioning) of the processing chamber, in order to reduce an amount of particle adders formed on the wafer, typically takes 5 hours to complete, resulting in a long downtime before the processing chamber can be used for additional molybdenum deposition.

Without intending to be bound by theory, the wafer temperature and process kit temperature may be different, with the wafer temperature being greater than the process kit temperature. Due at least in part to the temperature differences, the Mo layer on the process kit may have different properties than the film being deposited on the wafer. For example, the Mo on the process kit may have lower density and may also have high levels of impurities than the Mo film on the wafer. The particle adders formed from the Mo layer on the process kit thus may have detrimental properties that disrupt the uniformity of the Mo film deposited on the wafer. There are no known in situ cleaning processes capable of cleaning ALD molybdenum from the process kit, necessitating long equipment downtimes for cleanings and maintenance.

Additionally, plasma-based processes are prone to increased particulate contamination due to plasma-induced stress accumulation on the chamber body. For example, the particle lifetime of a process kit in a plasma process is 20% of the particle lifetime of a process kit in a thermal processing chamber.

Accordingly, there is a need for methods to extend the mean wafers between cleaning (MWBC) for molybdenum deposition processes.

### SUMMARY

Methods for extending MWBC in semiconductor processing chambers are provided. In some embodiments, the methods include a molybdenum deposition method including depositing molybdenum on one or more wafers in a dry cleaned and conditioned processing chamber to a predetermined total deposition thickness, an amount of particle adders on the one or more wafers increasing with deposition thickness from a first amount to a second amount; and exposing the processing chamber to a plasma treatment to reduce an amount of particle adders formed on subsequent wafers to a third amount below the second amount, the plasma treatment extending a time period between a dry cleaning and re-conditioning of the processing chamber.

In some embodiments, the methods include a molybdenum deposition method including forming a film comprising molybdenum on a surface of N wafers in a processing chamber using a plasma-enhanced deposition process, N being an integer in a range of from 1 to 100, the film comprising molybdenum having a total thickness summed over the N wafers of 4000 Å or greater; removing the N wafers from the processing chamber; and performing a plasma treatment in the processing chamber when no wafer is present to reduce a molybdenum accumulation in the processing chamber, the molybdenum accumulation being formed during the plasma-enhanced deposition process.

In some embodiments, the methods include a molybdenum deposition method including performing a process cycle in a processing chamber on N wafers, N being an integer in a range of from 1 to 100, each process cycle comprising exposing the N wafers to a molybdenum precursor in a plasma-enhanced deposition process to deposit a film comprising molybdenum on the N wafers; and cleaning the processing chamber after a total thickness of the film comprising molybdenum is 4000 Å or greater, the cleaning comprising performing a plasma treatment in the processing chamber when no wafer is present.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic representation of a processing chamber according to one or more embodiments;

FIG. 2 illustrates a flowchart of a process method according to one or more embodiments;

FIG. 3 illustrates a schematic representation of a wafer after molybdenum deposition with particle adder according to one or more embodiments;

FIGS. 4A through 4C illustrate a schematic representation of wafers with different amounts of particle adders according to one or more embodiments of the disclosure;

FIG. 5A illustrates an expanded view of region of FIG. 1 prior to a conditioning plasma treatment according to one or more embodiments; and

FIG. 5B illustrates a view of FIG. 5A after a conditioning plasma treatment according to one or more embodiments.

FIG. 6A illustrates a cross-sectional view of a wafer having a feature according to one or more embodiments.

FIG. 6B illustrates a cross-sectional view of a wafer having a feature that is filled with a molybdenum film according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “wafer” or “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “wafer” or “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

One or more embodiments of the disclosure are directed to deposition methods comprising exposing a process kit of a processing chamber having a precoated molybdenum layer thereon to a conditioning plasma treatment comprising hydrogen radicals to form a conditioned molybdenum layer. A molybdenum film is deposited on a plurality of wafers within the processing chamber.

Additional embodiments of the disclosure are directed to deposition methods comprising processing one or more wafers within a processing chamber to deposit molybdenum on the wafers. The process kit is conditioned after processing the plurality of wafers using a conditioning plasma treatment. The conditioning plasma treatment may comprise exposing the process kit to hydrogen radicals, or hydrogen and oxygen radicals.

Further embodiments of the disclosure are directed to non-transitory computer readable medium including instructions, that, when executed by a controller of a processing chamber, causes the processing chamber to perform operations of: exposing one or more wafers to a molybdenum precursor to deposit a molybdenum film on one or more wafers; and performing a conditioning plasma treatment in the processing chamber.

Embodiments of the disclosure are directed to methods of using a conditioning plasma treatment to reduce an amount of particle adders formed on subsequent wafers during plasma-assisted molybdenum deposition, and to extend the time period between dry cleaning and re-conditioning of the processing chamber. Without intending to be bound by theory, it is believed that the conditioning plasma treatment may improve properties of a precoated Mo layer formed on the process kit, wherein the precoated Mo layer may be degraded during the plasma-assisted molybdenum deposition on the one or more wafers. In some embodiments, the conditioning plasma treatment improves the properties of the Mo layer on the process kit by densifying the Mo layer. In some embodiments, the conditioning plasma treatment reduces molybdenum accumulation in the processing chamber. In some embodiments, the molybdenum accumulation is formed, at least in part, during the plasma-enhanced deposition of the molybdenum film on one or more wafers. Some embodiments of the disclosure provide a conditioning plasma treatment on one or more of the chamber showerhead, pumping liner, chamber isolator or edge ring. Some embodiments of the disclosure advantageously provide methods of improving adhesion of an Mo layer to the process kit during deposition. One or more embodiments advantageously provide methods of reducing particle contamination from a layer formed on the process kit. In some embodiments, the mean wafers between clean (MWBC) for a molybdenum deposition process is extended.

Some embodiments of the disclosure periodically treat the chamber body using a hydrogen (H₂) plasma treatment, or a hydrogen/oxygen (H₂/O₂) plasma treatment. Without being bound by any particular theory of operation, it is believed that the plasma treatment improves the adhesion of or densifies the Mo layer on the process kit. Some embodiments improve the adhesion of the Mo layer to the process kit over time. In some embodiments, adhesion is improved by lowering delamination, cracking from stressed films and/or showerhead peeling.

In some embodiments, the process particle performance is improved to increase the particle lifetime of the process kit, where particle performance may be defined by an amount of particle adders formed on the wafer undergoing plasma-assisted molybdenum deposition in the processing chamber after the treatment. In some embodiments, the amount of particle adders formed is in the range of less than 5 particle adders for a 300 mm wafer after the conditioning plasma treatment. In some embodiments, the number of particle adders formed after the conditioning plasma treatment is less than 50 particle adders for a 300 mm wafer, or less than 100 particle adders for a 300 mm wafer, or less than 250 particle adders for a 300 mm wafer, or less than 500 particle adders for a 300 mm wafer, or less than 1000 particle adders for a 300 mm wafer.

In some embodiments, the particle adders are measured using a surface inspection system using, for example, light-scattering. In some embodiments, the particle adders are measured using a scanning electron microscope (SEM) to determine the particle adder size based on image analysis. In some embodiments, a particle map and bin sizes are determined by optically measuring the surface topography aberrations that indicate defects on a wafer surface. At smaller particle sizes, the measured particle adder could be a wafer defect and not a particle added by the process and SEM can be used to view the top of the wafers before or after receiving the defect map from another technique. In some embodiments, SEM images are taken at locations on the defect map at one or more magnifications and be reviewed for the existence of particles, the correct bin size, particle morphology, and/or particle composition. In some embodiments, the particle adders may be characterized using total reflection X-ray fluorescence (TXRF).

In some embodiments, a hydrogen or hydrogen/oxygen plasma treatment at various powers, process gas flow ratios and/or treatment times reduces the particle adders formed on subsequent substrates during plasma-assisted Mo deposition.

The Mo layer on the process kit during deposition may have high impurities and may form a low-density layer that contributes to particle adder formation on the one or more wafers, decreasing the MWBC for the processing chamber in production. Some embodiments of the disclosure modify the film properties deposited on the process kit periodically during kit life to help keep the film adhered to the process kit, make the film denser and/or more stress-neutral so that defects are less likely to occur causing particle adders to dislodge. Some embodiments of the disclosure advantageously provide methods that can shorten the process time by using H₂/O₂ plasma treatment instead of NF₃ dry clean plus precoat.

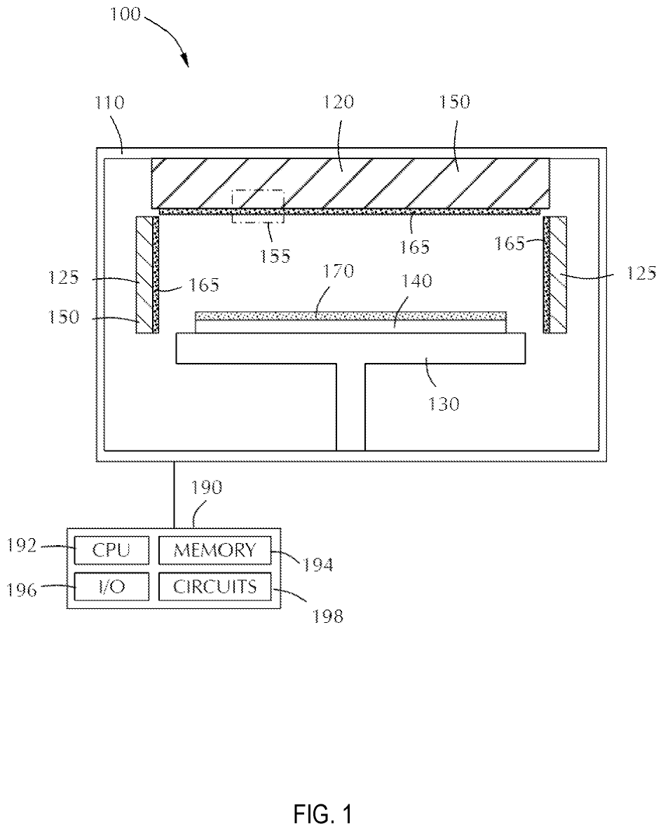

FIG. 1 illustrates a processing chamber 100 according to some embodiments. The processing chamber 100 illustrated in FIG. 1 includes a chamber body 110, a showerhead 120 (or other gas distribution plate), a confinement ring 125 (which may be omitted), a pedestal 130 (or other substrate support), and a wafer 140. The process kit 150 in FIG. 1 comprises the pedestal 130 and confinement ring 125. In some embodiment, the process kit 150 may have a conditioned Mo film 165. The conditioned Mo film 165 has been conditioned by a conditioning plasma treatment as described herein. The conditioning plasma treatment of some embodiments comprises hydrogen radicals.

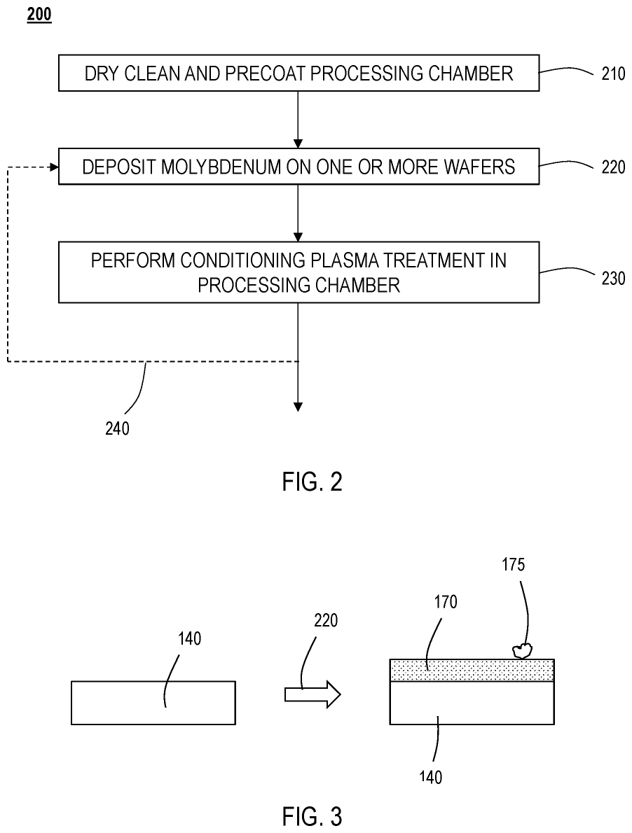

FIG. 2 illustrates a method 200 according to some embodiments of the disclosure. Referring to FIG. 2, at operation 210, in some embodiments, the processing chamber may be dry cleaned and precoated with molybdenum. As used in this specification and the appended claims, the term “dry clean”, and the like, refers to a gas based process using, typically, a halogenated compound. The precoating operation 210 of the processing chamber 100 may create the molybdenum layer 160 on the process kit 150.

At operation 220, in some embodiments, molybdenum is deposited on one or more wafers 140 to form a molybdenum film 170 on the one or more wafers 140 in the processing chamber 100. The deposited molybdenum film 170 may have a total deposition thickness, which is summed over the one or more wafers. For example, the thickness of the molybdenum film formed on the first wafer processed after operation 210 and the thickness of the molybdenum film formed on the second through nth wafer processed after operation 210 are added together in a running total.

In some embodiments, the one or more wafers 140 are processed individually. In some embodiments, wafers are removed from the processing chamber after processing and new wafers are introduced into the processing chamber for processing. In some embodiments, deposition occurs on more than one wafer at a time.

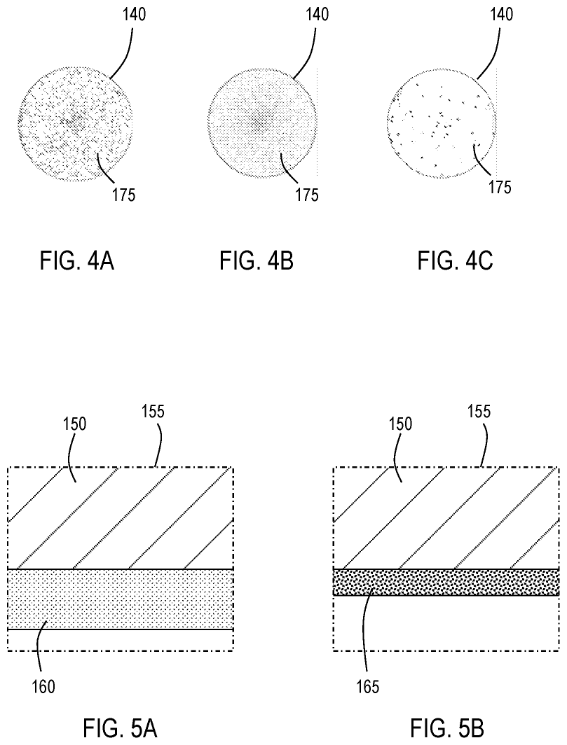

With reference to FIGS. 2 and 3, during operation 220, an amount of particle adders 175 may be deposited on the one or more wafers 140 with the molybdenum film 170. Specifically, the amount of particle adders 175 deposited may increase with increasing total deposition thickness. The amount of particle adders 175 may increase from a first amount, on the wafer 140 processed directly after the dry clean and precoating of the processing chamber at operation 210, to a second amount, after molybdenum has been deposited on the one or more wafers to the total deposition thickness. For example, as shown in the exemplary embodiment of FIGS. 4A and 4B, respectively. FIG. 4A shows the first wafer 140a with a first amount of particle adders 175 after operation 210, FIG. 4B shows the wafer 140b with a second amount of particle adders 175 after the total deposition thickness has been achieved, and FIG. 4C shows the first wafer 140c with a third amount of particle adders 175 after treatment at operation 230, as discussed further below.

In some embodiments, the first amount of particle adders 175 deposited on the first wafer 140 after operation 210 is less than or equal to 1500 particle adders per 300 mm wafer, as shown in FIG. 4A. In some embodiments, the first amount of particle adders 175 deposited on the first wafer 140 after operation 210 is less than or equal to 1250, 1000, 750, 500, 250 or 100 particle adders per 300 mm wafer. The skilled artisan will recognize that the number of particle adders 175 on the wafer 140 will depend on the size of the wafer 140 relative to the size of the process region of the processing chamber. In some embodiments, the first amount of particle adders 175 is in a range of from 1 to 1500 particle adders per 300 mm wafer, or in the range of 10 to 1000 particle adders per 300 mm wafer, or in the range of 100 to 500 particle adders per 300 mm wafer.

After depositing the predetermined total deposition thickness of molybdenum film 170, the wafer 140 will have a second amount of particle adders 175, as shown in FIG. 4B. The total deposition thickness is the sum of the molybdenum film 170 deposited on the one or more wafers 140. In some embodiments, the predetermined total deposition thickness of molybdenum film 170 is 4000 Å or greater. In some embodiments, the predetermined total deposition thickness is 2000 Å or greater. In some embodiments, the predetermined total deposition thickness is 6000 Å or greater. In some embodiments, the predetermined total deposition thickness is 8000 Å or greater, or 10000 Å or greater, or 15000 Å or greater, or 20000 Å or greater.

In some embodiments, the second amount of particle adders 175 is greater than or equal to 5000 particle adders per 300 mm wafer. In some embodiments, the second amount of particle adders 175 is greater than the first amount by a factor of 5× or more, or by a factor of 10× or more.

At operation 230, in some embodiments, a conditioning plasma treatment is performed in the processing chamber. In some embodiments, the conditioning plasma treatment may comprise H₂. In some embodiments, the conditioning plasma treatment may comprise H₂/O₂. In some embodiments, the conditioning plasma treatment consists essentially of the stated species. As used in this manner, the term “consists essentially of” means that the composition is greater than or equal to 95%, 98% or 99% of the stated species, or sum of the stated species.

The conditioning plasma treatment 230 has a substantially shorter duration than a convention dry clean and preconditioning process like that of operation 210. In some embodiments, the conditioning plasma treatment 230 may have a duration of less than or equal to five minutes, such as a duration of two minutes. In some embodiments, no wafers are present in the processing chamber during the conditioning plasma treatment.

In some embodiments, performing the conditioning plasma treatment 230 may cause a reduction in an amount of particle adders deposited on subsequent wafers during molybdenum deposition. In some embodiments, the reduction is from the second amount to a third amount, as measured on the first wafer after operation 230, and shown in FIG. 4C. In some embodiments, the third amount of particle adders is less than or equal to 25% of the first amount of particle adders, the first amount being the amount directly after dry clean and precoating operation 210 of the processing chamber 100. In some embodiments, the third amount is less than or equal to 1000 particle adders per 300 mm wafer. In some embodiments, the third amount is less than or equal to 500 particle adders per 300 mm wafer, or less than or equal to 200 particle adders per 300 mm wafer, or less than or equal to 100 particle adders per 300 mm wafer, or less than or equal to 50 particle adders per 300 mm wafer, or less than or equal to 10 particle adders per 300 mm wafer.

In some embodiments, an optional process cycle 240 is performed. The optional process cycle 240 may comprise depositing molybdenum 220 to form a film comprising molybdenum, the film comprising molybdenum having a total deposition thickness, and performing a conditioning plasma treatment 230 on the processing chamber 100. The optional process cycle 240 may be repeated a number of times, so as to increase a total amount of the one or more wafers that can be processed before the processing chamber must be subjected to dry cleaning and conditioning. In some embodiments, the total amount of the one or more wafers that can be processed before operation 210 is repeated is increased by a factor of 5× or greater relative to not performing the conditioning plasma treatment at operation 230.

At each optional process cycle 240 (repeat of operation 220 and operation 230), the number of particle adders being deposited on subsequent wafers is reduced to the third amount, which is lower than the second amount of particle adders deposited on the one or more wafers immediately before performing the conditioning plasma treatment at operation 230. By performing one or more process cycles 240, the total number of the one or more wafers having a deposited molybdenum film can be increased, relative to not performing the conditioning plasma treatment 230. In some embodiments, the total number of the one or more wafers can be increased by a factor of 2× or more relative to not using the conditioning plasma treatment 230. In some embodiments, the total number of the one or more wafers can be increased by a factor of 5× or more, or by a factor of 10× or more. In some embodiments, operation 230 is performed after each wafer. In some embodiments, operation 230 is performed based on a number of wafers that are processed, for example, at every 2, 3, 4, 5, 6, 7, 8, 9, 10, 15, 20 or 25 wafers. In some embodiments, operation 230 is performed at every N wafers that are processed, wherein N is an integer in a range from 1 to 100. In some embodiments, operation 230 is performed after the predetermined total deposition thickness of the molybdenum film 170 is deposited. The total deposition thickness is the sum of the film thicknesses of each of the N wafers that are processed.

FIG. 5A illustrates an expanded view of region 155 before the conditioning plasma treatment 230. In some embodiments, during the molybdenum deposition process 220 on the one or more wafers 140, molybdenum may be deposited on the molybdenum layer 160 on the process kit 150 (e.g., showerhead 120 and/or confinement ring 125). The molybdenum layer 160 on the process kit 150 may have different properties than the molybdenum film 170 deposited on the one or more wafers 140, where these different properties may be undesirable and may lead to a reduced device yield. Without intending to be bound by theory, the differences in properties between the molybdenum film 160 molybdenum layer 170 are due to, inter alia, temperature differentials between the wafer 140 and the process kit 150.

Referring to FIG. 5A, the molybdenum layer 160 on the process kit 150 may have a relatively low density. FIG. 5B illustrates an expanded view of region 155 after the conditioning plasma treatment 230. In some embodiments, the conditioning plasma treatment 230 may increase the density of the molybdenum layer 160 on the process kit to form the conditioned molybdenum layer 165 on process kit 150. In some embodiments, the conditioned molybdenum layer 165 may be referred to as a densified molybdenum layer.

In some embodiments, the molybdenum layer 160 is formed by a precoating process at operation 210 and deteriorates during the deposition at operation 220 of the molybdenum film 170 on the one or more wafers 140.

In some embodiments, the molybdenum film 170 is deposited by a plasma-assisted deposition process. Some non-limiting examples of plasma-assisted deposition processes include plasma-enhanced atomic layer deposition (PE-ALD) and plasma-enhanced chemical vapor deposition (PE-CVD). In some embodiments, the molybdenum film 170 is deposited by plasma-enhanced atomic layer deposition. In some embodiments, the molybdenum film 170 is deposited by plasma-enhanced chemical vapor deposition. In some embodiments, the molybdenum film 170 is deposited on a plurality of wafers at the same time or sequentially.

In some embodiments, the conditioning plasma treatment at operation 230 comprises a plasma with a frequency in the range of 2 MHz to 100 MHz, or a frequency of 2 MHZ, 13.56 MHz, 40 MHz, 60 MHz or 100 MHz. In some embodiments, the conditioning gas comprises a plasma with a pressure in the range of 0.5 torr to 25 torr, or in the range of 1 torr to 15 torr, or in the range of 1.5 torr to 10 torr. In some embodiments, the conditioning gas comprises a plasma and the conditioning process is performed for less than or equal to five minutes. In some embodiments, the conditioning gas comprises a plasma and the conditioning process takes less time than a regular NF₃ dry clean plus precoat time.

In some embodiments, the one or more wafers 140 comprise one or more features. For example, a feature may be, or may include, a trench structure, a via structure, or an aperture formed within the wafer. Although the wafer features may be characterized by any shapes or sizes, in some embodiments the wafer features are characterized by higher aspect ratios, or a ratio of the depth of the feature to a width across the feature. For example, in some embodiments, wafer features are characterized by aspect ratios greater than or equal to 5:1. In some embodiments wafer features are characterized by aspect ratios greater than or equal to 10:1, greater than or equal to 15:1, greater than or equal to 20:1, greater than or equal to 25:1, greater than or equal to 30:1, greater than or equal to 40:1, or greater than or equal to 50:1. Additionally, the features may be characterized by narrow widths or diameters across the feature including between two sidewalls, such as a dimension less than or equal to 25 nm, and may be characterized by a width across the feature of less than or equal to 15 nm, less than or equal to 12 nm, less than or equal to 10 nm, less than or equal to 9 nm, less than or equal to 8 nm, less than or equal to 7 nm, less than or equal to 6 nm, less than or equal to 5 nm, or less.

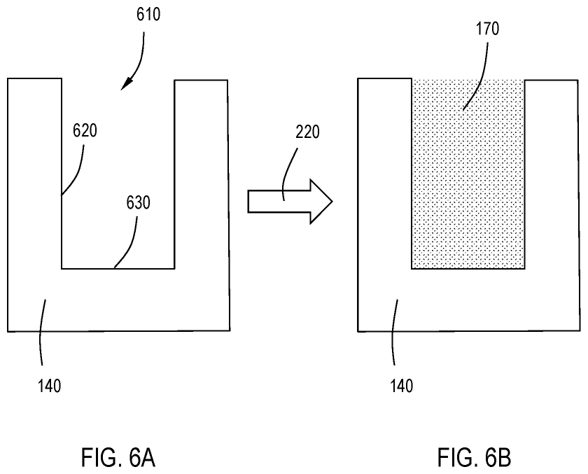

For example, FIGS. 6A and 6B illustrate a wafer 140 comprising a trench feature 610. Referring to FIG. 6A, in some embodiments, prior to molybdenum deposition at operation 220, the trench feature 610 comprises a sidewall surface 620 and a bottom 630.

In some embodiments, the molybdenum deposition at operation 220 deposits the molybdenum film 170 as a gapfill inside the trench feature 610 to fill the trench feature 610 with the molybdenum film 170.

With reference to FIG. 1, additional embodiments of the disclosure are directed to processing chambers 100 for executing the methods described herein. FIG. 1 illustrates a processing chamber 100 that can be used to process a substrate according to one or more embodiment of the disclosure. The processing chamber 100 comprises at least one controller 190 configured to control various components of the chamber 100. In some embodiments, there is more than processor connected to the processing chamber 100 with a primary control processor coupled to each of the separate processors to control the chamber 100. The controller 190 may be one of any form of general-purpose computer processor, microcontroller, microprocessor, etc., that can be used in an industrial setting for controlling various chambers and sub-processors.

In some embodiments, the controller 190 has a processor 192 (also referred to as a CPU), a memory 194 coupled to the processor 192, input/output devices 196 coupled to the processor 192, and support circuits 198 to communication between the different electronic components. In some embodiments, the memory 194 includes one or more of transitory memory (e.g., random access memory) or non-transitory memory (e.g., storage).

The memory 194, or computer-readable medium, of the processor may be one or more of readily available memory such as random access memory (RAM), read-only memory (ROM), floppy disk, hard disk, or any other form of digital storage, local or remote. The memory 194 can retain an instruction set that is operable by the processor 192 to control parameters and components of the system. The support circuits 198 are coupled to the processor 192 for supporting the processor in a conventional manner. Circuits may include, for example, cache, power supplies, clock circuits, input/output circuitry, subsystems, and the like.

Processes may generally be stored in the memory as a software routine that, when executed by the processor, causes the processing chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In some embodiments, the controller 190 has one or more configurations to execute individual processes or sub-processes to perform the method. In some embodiments, the controller 190 is connected to and configured to operate intermediate components to perform the functions of the methods. For example, the controller 190 of some embodiments is connected to and configured to control one or more of gas valves, actuators, motors, slit valves, vacuum control, etc.

The controller 190 of some embodiments has one or more configurations selected from: a configuration to expose a substrate to a deposition process condition to deposit a molybdenum film; a configuration to expose a process kit of the processing chamber to a conditioning process. A non-transitory computer readable medium including instructions, that, when executed by a controller of a processing chamber, causes the processing chamber to perform operations of: depositing molybdenum on one or more wafers in a dry cleaned and conditioned processing chamber to a predetermined total deposition thickness, an amount of particle adders on the one or more wafers increasing with deposition thickness from a first amount to a second amount; and exposing the processing chamber to a plasma treatment to reduce an amount of particle adders formed on subsequent wafers to a third amount below the second amount, the plasma treatment extending a time period between a dry cleaning and re-conditioning of the processing chamber.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A molybdenum deposition method comprising:
depositing molybdenum on one or more wafers in a dry cleaned and conditioned processing chamber to a predetermined total deposition thickness, an amount of particle adders on the one or more wafers increasing with deposition thickness from a first amount to a second amount; and
exposing the processing chamber to a plasma treatment to reduce an amount of particle adders formed on subsequent wafers to a third amount below the second amount, the plasma treatment extending a time period between a dry cleaning and re-conditioning of the processing chamber.

2. The molybdenum deposition method of claim 1, wherein the first amount of particle adders on the one or more wafers is greater than 1500 particle adders per 300 mm wafer.

3. The molybdenum deposition method of claim 1, wherein the second amount of particle adders on the one or more wafers is greater than 5000 particle adders per 300 mm wafer.

4. The molybdenum deposition method of claim 1, wherein the third amount of particle adders on the one or more wafers is less than 25% of the first amount.

5. The molybdenum deposition method of claim 1, wherein the predetermined total deposition thickness is 4000 Å or greater.

6. The molybdenum deposition method of claim 1, wherein a surface of the one or more wafers comprises one or more features, and the molybdenum is deposited in the one or more features to fill the one or more features.

7. The molybdenum deposition method of claim 1, wherein the depositing molybdenum on the one or more wafers comprises a plasma-enhanced atomic layer deposition (PE-ALD) process or a plasma-enhanced chemical vapor deposition (PE-CVD) process.

8. The molybdenum deposition method of claim 1, wherein the plasma treatment comprises a duration of less than 5 minutes.

9. The molybdenum deposition method of claim 1, wherein the plasma treatment comprises H₂ or H₂/O₂.

10. A molybdenum deposition method comprising:
forming a film comprising molybdenum on a surface of N wafers in a processing chamber using a plasma-enhanced deposition process, N being an integer in a range of from 1 to 100, the film comprising molybdenum having a total thickness summed over the N wafers of 4000 Å or greater;
removing the N wafers from the processing chamber; and
performing a plasma treatment in the processing chamber when no wafer is present to reduce a molybdenum accumulation in the processing chamber, the molybdenum accumulation being formed during the plasma-enhanced deposition process.

11. The molybdenum deposition method of claim 10, wherein the surface of the N wafers comprises one or more features, and the molybdenum is deposited in the one or more features to fill the one or more features.

12. The molybdenum deposition method of claim 10, wherein the plasma-enhanced deposition process comprises a plasma-enhanced atomic layer deposition (PE-ALD) process or a plasma-enhanced chemical vapor deposition (PE-CVD) process.

13. The molybdenum deposition method of claim 10, wherein the plasma treatment comprises a duration of less than 5 minutes.

14. The molybdenum deposition method of claim 10, wherein the plasma treatment comprises H₂ or H₂/O₂.

15. A molybdenum deposition method comprising:
performing a process cycle in a processing chamber on N wafers, N being an integer in a range of from 1 to 100, each process cycle comprising exposing the N wafers to a molybdenum precursor in a plasma-enhanced deposition process to deposit a film comprising molybdenum on the N wafers; and
cleaning the processing chamber after a total thickness of the film comprising molybdenum is 4000 Å or greater, the cleaning comprising performing a plasma treatment in the processing chamber when no wafer is present.

16. The molybdenum deposition method of claim 15, wherein a number of process cycles that can be performed between dry cleaning and re-conditioning the processing chamber is increased by five times or more relative to not performing the plasma treatment in the processing chamber.

17. The molybdenum deposition method of claim 15, wherein a surface of the N wafers comprises one or more features, and the molybdenum is deposited in the one or more features to fill the one or more features.

18. The molybdenum deposition method of claim 15, wherein the plasma-enhanced deposition process comprises a plasma-enhanced atomic layer deposition (PE-ALD) process or a plasma-enhanced chemical vapor deposition (PE-CVD) process.

19. The molybdenum deposition method of claim 15, wherein the plasma treatment comprises a duration of less than 5 minutes.

20. The molybdenum deposition method of claim 15, wherein the plasma treatment comprises H₂ or H₂/O₂.
